(19) United States
(12) Patent Application Publication
(10) Pub. No.: US 2025/0324911 A1
(43) Pub. Date: Oct. 16, 2025

(54) ULTRASONIC TRANSDUCING DEVICE AND MANUFACTURING METHOD THEREOF

(71) Applicant: QISDA CORPORATION, Taoyuan City (TW)

(72) Inventor: Fu-Sheng Jiang, Taoyuan City (TW)

(73) Assignee: QISDA CORPORATION, Taoyuan City (TW)

(21) Appl. No.: 19/017,762

(22) Filed: Jan. 12, 2025

(30) Foreign Application Priority Data
Apr. 10, 2024 (TW) 113113335

(51) Int. Cl. H10N 30/20; H10N 30/063; H10N 30/088; H10N 30/87

(52) U.S. Cl. CPC H10N 30/20; H10N 30/063; H10N 30/088; H10N 30/87

(57) ABSTRACT

An ultrasonic transducing device is applied by a manufacturing method and includes a piezoelectric material layer, a two-dimensional electrode array and a row and column electrode array. The piezoelectric material layer has a first surface and a second surface opposite to each other, and the piezoelectric material layer is divided into grid-shaped units. The two-dimensional electrode array is disposed on the first surface and has a plurality of two-dimensional electrode units that are electrically independent. The row and column electrode array is disposed on the second surface and has a row electrode assembly and a column electrode assembly. The electrode rows of the row electrode assembly are electrically independent, and the row electrode units of each electrode row are electrically connected to each other. The electrode columns of the column electrode assembly are electrically independent, and the column electrode units of each electrode column are electrically connected to each other.

### BACKGROUND OF THE INVENTION

### 1. Field of the Invention

The present invention relates to an ultrasonic transducing device and a manufacturing method, and more particularly, to an ultrasonic transducing device using a small number of control lines to scan a large range and a manufacturing method related to the ultrasonic transducing device.

### 2. Description of the Prior Art

The electrode units of the conventional two-dimensional array-type ultrasonic transducer are independently controlled; the conventional two-dimensional array-type ultrasonic transducer may have high degree of program controllability, but consumes a large number of system channels and has artifact defects that are difficult to solve. Another conventional row-column array ultrasonic transducer includes the column electrode assembly and the row electrode assembly. One of the column electrode assembly and the row electrode assembly emits the ultrasonic signal, and another electrode assembly of the column electrode assembly and the row electrode assembly receive the ultrasonic signal, which may decrease the number of system channels, but has drawbacks of poor signal-to-noise ratio and limited scanning range. Therefore, design of an ultrasonic transducing device that takes into account advantages of the two-dimensional array-type ultrasonic transducer and the row-column array ultrasonic transducer but does not require the large number of system channels and can execute the large scale scanning operation is an important issue in the medical examination industry.

### SUMMARY OF THE INVENTION

The present invention provides an ultrasonic transducing device using a small number of control lines to scan a large range and a manufacturing method related to the ultrasonic transducing device for solving above drawbacks.

According to the claimed invention, an ultrasonic transducing device includes a piezoelectric material layer, a two-dimensional electrode array and a row and column electrode array. The piezoelectric material layer has a first surface and a second surface opposite to each other, and includes a plurality of grid-shaped units via division. The two-dimensional electrode array is disposed on the first surface and comprising plural two-dimensional electrode units set in an electrically independent manner. The row and column electrode array is disposed on the second surface and includes a row electrode assembly and a column electrode assembly; plural electrode rows of the row electrode assembly are set in the electrically independent manner, and plural row electrode units of each electrode row are electrically connected to each other; plural electrode columns of the column electrode assembly are set in the electrically independent, and plural column electrode units of each electrode column are electrically connected to each other.

According to the claimed invention, a manufacturing method applied to an ultrasonic transducing device includes dividing the piezoelectric material layer into a plurality of grid-shaped units, coating anisotropic conductive adhesive on a first surface and a second surface of the piezoelectric material layer that are opposite to each other, fixing a two-dimensional electrode array on the first surface via the anisotropic conductive adhesive, and fixing a row and column electrode array on the second surface via the anisotropic conductive adhesive.

The ultrasonic transducing device of the present invention can combine advantages of the two-dimensional electrode array and the row and column electrode array while eliminating disadvantages. In the preferred embodiment, each two-dimensional electrode unit of the two-dimensional electrode array can be used to independently emit the ultrasonic signal for the large scale scanning operation, and the row electrode assembly or the column electrode assembly of the row and column electrode array can be further used to alternately receive the ultrasonic signal, so as to conform to a requirement of the large scale scanning operation by small increase of the channel number, thereby applying for the current ultrasonic system. Besides, the ultrasonic transducing device of the present invention can accurately control the intervals between the two-dimensional electrode array and each electrode unit of the row and column electrode array, which can effectively eliminate artifacts and provide preferred performance of resolution. The ultrasonic signal emitted by the two-dimensional electrode array can be used for energy healing, and therefore the ultrasonic transducing device of the present invention can further accomplish combination design of diagnosis and treatment.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded diagram of an ultrasonic transducing device according to an embodiment of the present invention.

FIG. 2 and FIG. 3 are diagrams of a piezoelectric material layer according to different embodiments of the present invention.

FIG. 4 is a diagram of a two-dimensional electrode array and related wires according to the embodiment of the present invention.

FIG. 5 is a diagram of the two-dimensional electrode array and related wires in other types according to the embodiment of the present invention.

FIG. 6 is a diagram of a row and column electrode array and related wires according to the embodiment of the present invention.

FIG. 7 is a diagram of the row and column electrode array and the related wires in other types according to the embodiment of the present invention.

FIG. 8 is a flow chart of a manufacturing method suitable for the ultrasonic transducing device according to the embodiment of the present invention.

### DETAILED DESCRIPTION

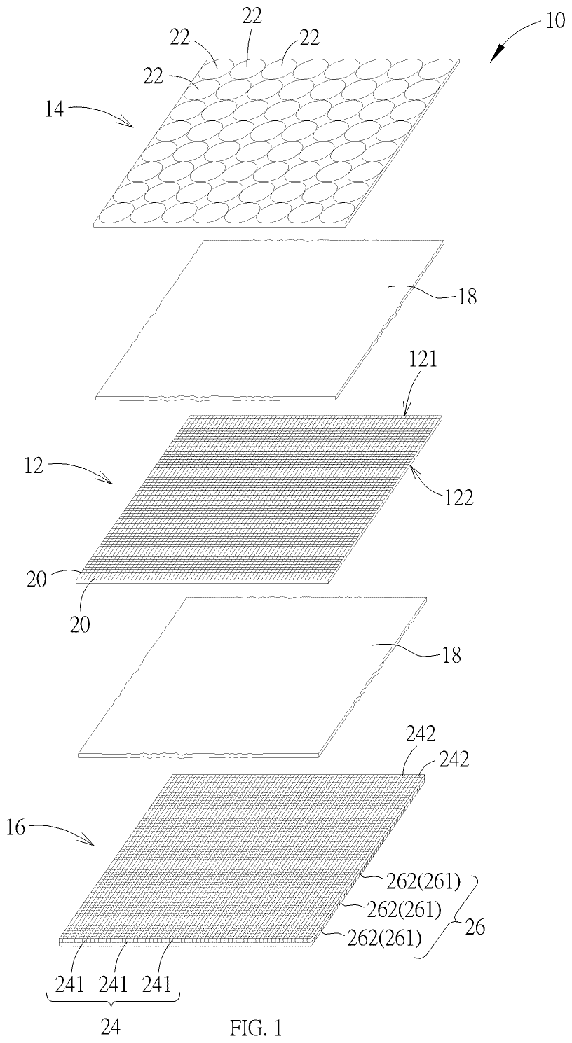

Please refer to FIG. 1. FIG. 1 is an exploded diagram of an ultrasonic transducing device 10 according to an embodiment of the present invention. The ultrasonic transducing device 10 can include a piezoelectric material layer 12, a two-dimensional electrode array 14, a row and column electrode array 16 and anisotropic conductive adhesive 18. The two-dimensional electrode array 14 and the row and column electrode array 16 can be respectively disposed on two opposite surfaces of the piezoelectric material layer 12. The anisotropic conductive adhesive 18 can be disposed between the piezoelectric material layer 12 and the two-dimensional electrode array 14, and further between the piezoelectric material layer 12 and the row and column electrode array 16 for providing a directional conductive property. In the preferred embodiment, the ultrasonic transducing device 10 can utilize the two-dimensional electrode array 14 to emit an ultrasonic signal, and further utilize the row and column electrode array 16 to receive the ultrasonic signal, so as to apply to the current ultrasonic system for large scale scanning operation; practical application of the ultrasonic transducing device 10 is not limited to the foresaid embodiment.

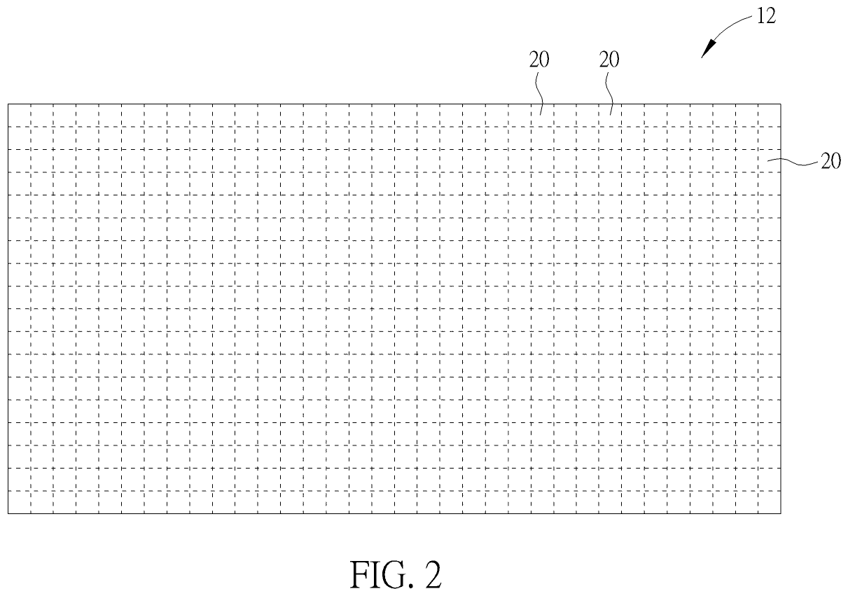

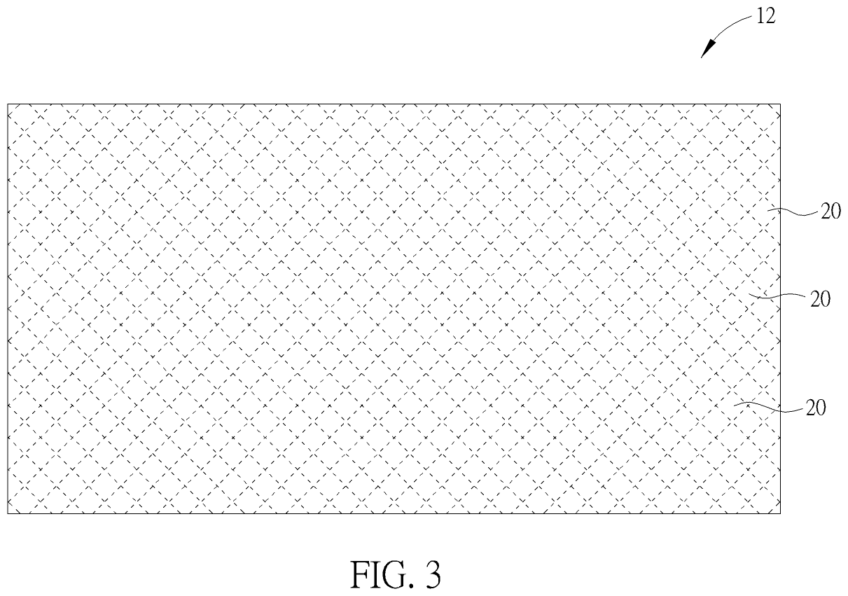

Please refer to FIG. 1 to FIG. 3. FIG. 2 and FIG. 3 are diagrams of the piezoelectric material layer 12 according to different embodiments of the present invention. The piezoelectric material layer 12 can have a first surface 121 and a second surface 122 opposite to each other. The first surface 121 can be a back surface of the ultrasonic transducing device 10 away from a target object. The second surface 122 can be a matched surface of the ultrasonic transducing device 10 facing the target object. The target object is an object detected by the ultrasonic transducing device 10, and not shown in the figures. Therefore, the first surface 121 and the second surface 122 can respectively be an electrical positive surface and an electrical negative surface of the piezoelectric material layer 12, and can be respectively and electrically connected with the two-dimensional electrode array 14 and the row and column electrode array 16 via the anisotropic conductive adhesive 18; practical application of the electrical connection is not limited to the foresaid embodiment.

The piezoelectric material layer 12 can be divided into a plurality of plurality of grid-shaped units 20. A cutting groove (which is not marked in the figures) formed between the adjacent grid-shaped units 20 can penetrate through the piezoelectric material layer 12 completely or partly, and intervals between the plurality of grid-shaped units 20 can be the same or different, which depends on a design demand. In addition, the plurality of grid-shaped units 20 divided on the first surface 121 and the second surface 122 of the piezoelectric material layer 12 can be aligned with other, or may be not aligned with other, which depends on the design demand. As the embodiment shown in FIG. 2, the piezoelectric material layer 12 can be divided into the plurality of grid-shaped units 20 in a longitudinal direction and in a transverse direction; as the embodiment shown in FIG. 3, the piezoelectric material layer 12 can be divided into the plurality of grid-shaped units 20 in a diagonal direction. The foresaid embodiments can be both applied for the ultrasonic transducing device 10 of the present invention.

That is to say, row-column cutting can be applied for the first surface 121 of the piezoelectric material layer 12, such as the embodiment shown in FIG. 2, and diagonal cutting can be applied for the second surface 122 of the piezoelectric material layer 12, such as the embodiment shown in FIG. 3. Or, the diagonal cutting (such as the embodiment shown in FIG. 3) can be applied for the first surface 121 of the piezoelectric material layer 12, and the row-column cutting (such as the embodiment shown in FIG. 2) can be applied for the second surface 122 of the piezoelectric material layer 12. Or, the row-column cutting (such as the embodiment shown in FIG. 2) can be applied for both the first surface 121 and the second surface 122 of the piezoelectric material layer 12, or the diagonal cutting (such as the embodiment shown in FIG. 3) can be applied for both the first surface 121 and the second surface 122 of the piezoelectric material layer 12.

Please refer to FIG. 1. The two-dimensional electrode array 14 can be preferably disposed on the first surface 121 of the piezoelectric material layer 12, and the row and column electrode array 16 can be preferably disposed on the second surface 122 of the piezoelectric material layer 12; however, position of the two-dimensional electrode array 14 and the row and column electrode array 16 can be interchangeable. The two-dimensional electrode array 14 can include plural two-dimensional electrode unit 22 set in an electrically independent manner. A shape of the two-dimensional electrode unit 22 is not limited to a circular type, and may be a square type, a rhombus type or a polygonal type, which depends on the design demand. The row and column electrode array 16 can include a row electrode assembly 24 and a column electrode assembly 26 that are assembled and overlapped with each other. The row electrode assembly 24 can include plural electrode rows 241 that are set in the electrically independent manner, and plural row electrode units 242 of each electrode row 241 can be electrically connected to each other. The column electrode assembly 26 can include plural electrode columns 261 that are set in the electrically independent manner, and plural column electrode units 262 of each electrode column 261 can be electrically connected to each other.

In the present invention, a size of the grid-shaped units 20 can be smaller than or equal to a size of the row electrode unit 242 or the column electrode unit 262 of the row and column electrode array 16; thus, the maximal size of the grid-shaped units 20 can be the same as the size of the row electrode unit 242 or the column electrode unit 262. Besides, the size of the grid-shaped units 20 can be smaller than the size of the two-dimensional electrode unit 22, and practical application of the size relation is not limited to the foresaid embodiment. In the preferred embodiment of the present invention, a number of the two-dimensional electrode units 22 of the two-dimensional electrode array 14 can be the same as the number of the electrode rows 241 and the number of the electrode columns 261. For example, the two-dimensional electrode array 14 can be an eight-by-eight matrix, and the number of the two-dimensional electrode unit 22 can be sixty-four; the row electrode assembly 24 can include the electrode rows 241 with sixty-four channels, and the column electrode assembly 26 can include the electrode columns 261 with sixty-four channels, so that the row and column electrode array 16 can have a total of one hundred and twenty-eight channels.

Moreover, the plural two-dimensional electrode units 22, the row electrode assembly 24 and the column electrode assembly 26 can be respectively designed as a rectangular array. A ratio of an arrangement number of the two-dimensional electrode units 22 on a side of the rectangular array to a row number of the row electrode assembly 24 (or a column number of the column electrode assembly 26) can be the same as a size ratio of each row and column electrode unit (such as the row electrode unit 242 or the column electrode unit 262) of the row electrode assembly 24 to each two-dimensional electrode unit 22. For example, the arrangement number of the plural two-dimensional electrode units 22 on the side of the rectangular array can be eight, and the row number of the row electrode assembly 24 (or the column number of the column electrode assembly 26) can have sixty-four channels, so that its ratio can be one eighth; the row and column electrode unit (such as the row electrode unit 242 or the column electrode unit 262) can be designed to comply with one half wavelength, and have a pitch equal to 0.2 millimeter, so the two-dimensional electrode unit 22 can be designed to comply with four times the wavelength, and the size ratio of the row and column electrode unit to the two-dimensional electrode unit 22 can be one eighth, which is the same as the ratio (which means one eighth mentioned as above) of the arrangement number of the two-dimensional electrode units 22 on the side of the rectangular array to the row number of the row electrode assembly 24.

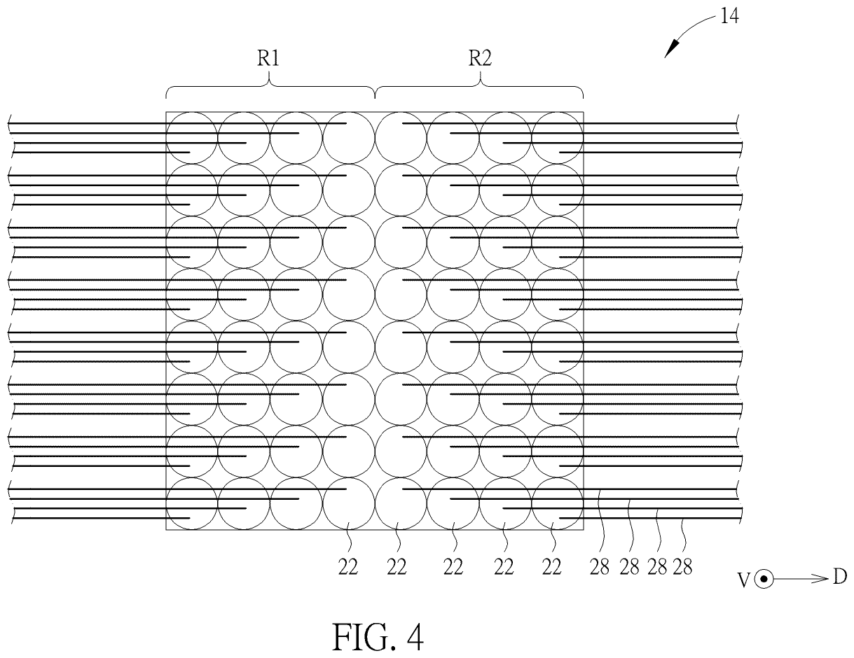

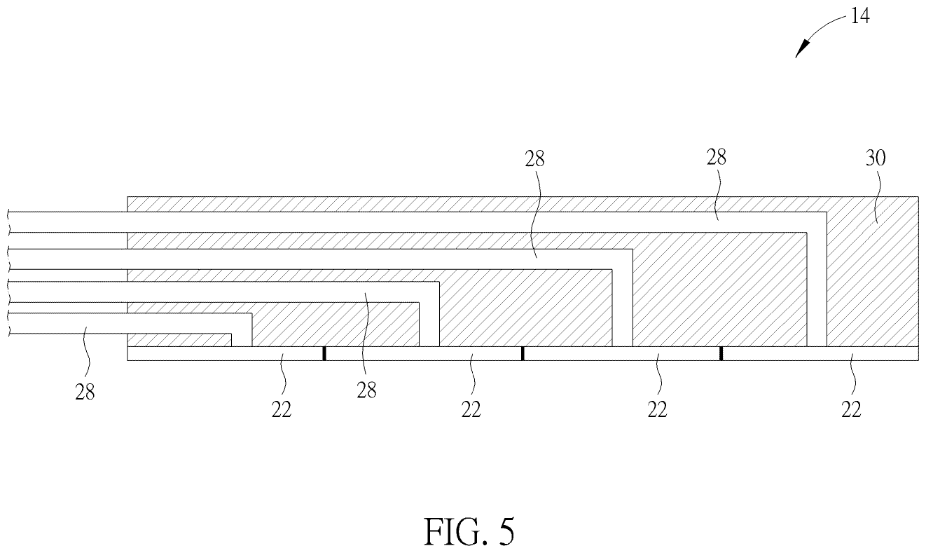

Please refer to FIG. 4 and FIG. 5. FIG. 4 is a diagram of the two-dimensional electrode array 14 and related wires according to the embodiment of the present invention. FIG. 5 is a diagram of the two-dimensional electrode array 14 and related wires in other types according to the embodiment of the present invention. The two-dimensional electrode array 14 can further include plural two-dimensional wires 28 respectively connected with the plural two-dimensional electrode units 22, and an extending direction D of each two-dimensional wire 28 can be substantially perpendicular to a planar normal vector V of the two-dimensional electrode unit 22; for example, the extending direction D can be a horizontal direction on the figure, and the planar normal vector V can be a vertical direction on the figure. As the embodiment shown in FIG. 4, every four two-dimensional electrode units 22 can be assigned as a set and are matched with the corresponding four two-dimensional wires 28. A sum of each wire width of the four two-dimensional wires 28 can be smaller than a size of each two-dimensional electrode unit 22, and therefore the four two-dimensional wires 28 can be extended outside the two-dimensional electrode array 14 in a side-by-side manner without contacting each other. As the embodiment in FIG. 5, every four two-dimensional electrode units 22 can be assigned as a set and are matched with the corresponding two-dimensional wires 28, and the four two-dimensional wires 28 can be overlapped with other; an isolation layer 30 can be disposed between any of the adjacent two-dimensional wires 28 to form a height difference for bridging connection. The isolation layer 30 can be various types of packaging material, and used to isolate and fix the two-dimensional wires 28. In the foresaid embodiment, a number of the two-dimensional electrode unit 22 in each set is not limited to four, and depends on the design demand.

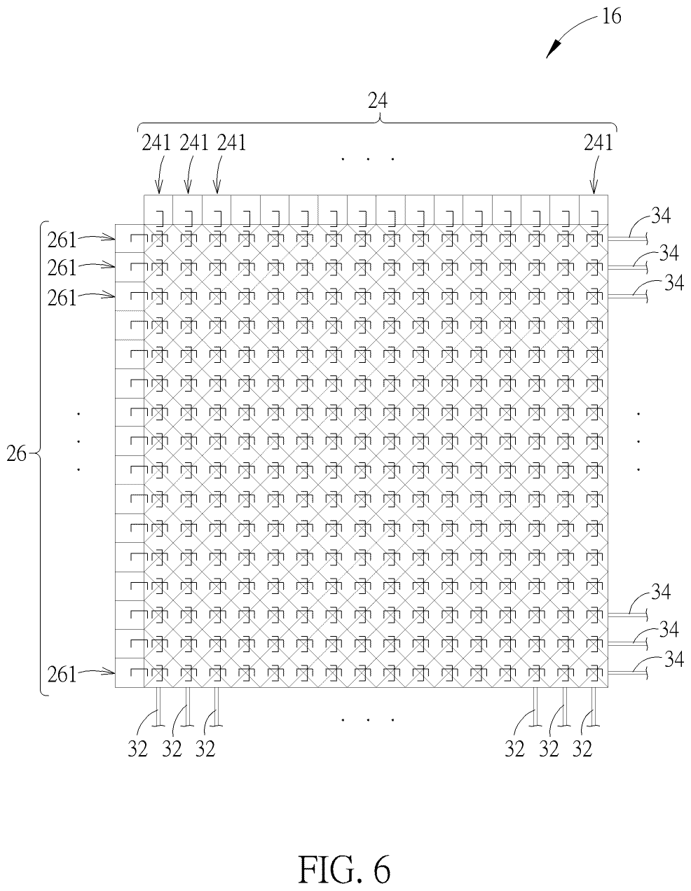

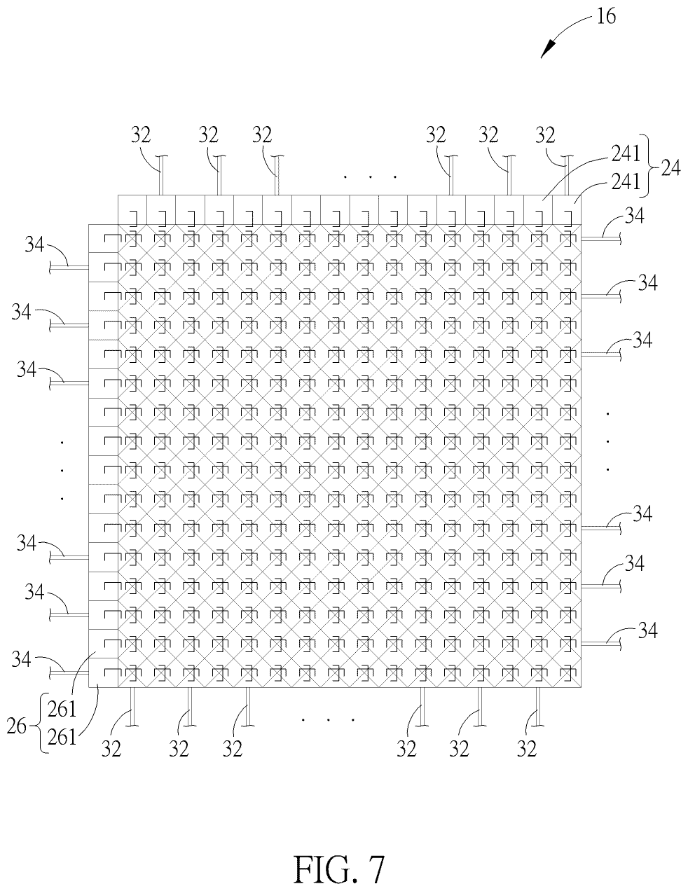

Please refer to FIG. 6 and FIG. 7. FIG. 6 is a diagram of the row and column electrode array 16 and related wires according to the embodiment of the present invention. FIG. 7 is a diagram of the row and column electrode array 16 and the related wires in other types according to the embodiment of the present invention. It should be mentioned that the row and column electrode array 16 can preferably have sixty-four electrode rows 241 and sixty-four electrode columns 261 in the preferred embodiment; however, content in FIG. 6 and FIG. 7 is only an example and does not include sixty-four sets of the electrode row 241 and the electrode column 261, which will be explained later. In addition, electrode patterns of the row and column electrode array 16 shown in FIG. 6 and FIG. 7 does not belong to a design scope of the present invention, and a detailed description is omitted herein for simplicity. The row and column electrode array 16 can include plural row wires 32 and plural column wires 34, respectively disposed on different sides of the row and column electrode array 16. As the embodiment shown in FIG. 6, the plural row wires 32 can be disposed on the same side of the row and column electrode array 16, and the plural column wires 34 can be disposed on the same side of the row and column electrode array 16 that is different from the side where on the plural row wires 32 are disposed. As the embodiment shown in FIG. 7, the plural row wires 32 can be alternately disposed on two opposite sides of the row and column electrode array 16, and the plural column wires 34 can be alternately disposed on two opposite sides of the row and column electrode array 16 that are different from the opposite sides where on the plural row wires 32 are disposed.

In the preferred embodiment of the present invention, the ultrasonic transducing device 10 can utilize the two-dimensional electrode array 14 to emit the ultrasonic signal, and utilize the row electrode assembly 24 and/or the column electrode assembly 26 to alternately receive the ultrasonic signal, so as to comply with the current ultrasonic system. Further, the ultrasonic transducing device 10 may utilize at least one of the row electrode assembly 24 and the column electrode assembly 26 to emit the ultrasonic signal, and utilize the two-dimensional electrode array 14 and/or another electrode assembly of the row electrode assembly 24 and the column electrode assembly 26 to receive the ultrasonic signal. Further, the ultrasonic transducing device 10 may divide the two-dimensional electrode array 14 at least into a first region R1 and a second region R2, for example, a left part shown in FIG. 4 can be the first region R1, and a right part shown in FIG. 4 can be the second region R2; the ultrasonic transducing device 10 may utilize the first region R1 to emit the ultrasonic signal and further utilize the second region R2 to receive the ultrasonic signal. Practical application of the ultrasonic transducing device 10 is not limited to the foresaid embodiment, and depends on the design demand.

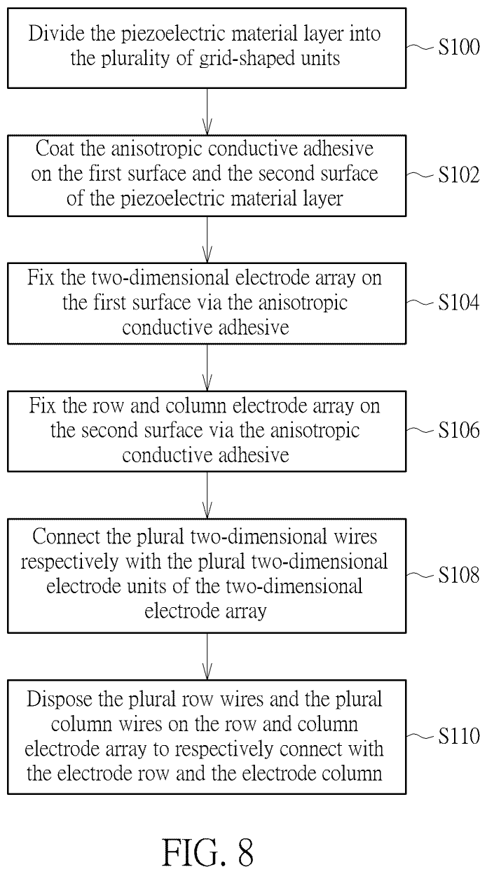

Please refer to FIG. 8. FIG. 8 is a flow chart of a manufacturing method suitable for the ultrasonic transducing device 10 according to the embodiment of the present invention. First, step S100 can be executed to divide the piezoelectric material layer 12 into the plurality of grid-shaped units 20. A grid arrangement direction of the plurality of grid-shaped units 20 on the first surface 121 of the piezoelectric material layer 12 can be the same as or different from a grid arrangement direction of the plurality of grid-shaped units 20 on the second surface 122 of the piezoelectric material layer 12, such as the embodiments shown in FIG. 2 and FIG. 3. Then, step S102, step S104 and step S106 can be executed to coat the anisotropic conductive adhesive 18 respectively on the first surface 121 and the second surface 122 of the piezoelectric material layer 12, and fix the two-dimensional electrode array 14 on the first surface 121 via the anisotropic conductive adhesive 18, and further fix the row and column electrode array 16 on the second surface 122 via the anisotropic conductive adhesive 18. Then, step S108 can be executed to connect the plural two-dimensional wires 28 respectively with the plural two-dimensional electrode units 22; as the embodiments shown in FIG. 4 and FIG. 5, the isolation layer 30 can be disposed between the adjacent two-dimensional wires 28 to form the height difference for the bridging connection, or the adjacent two-dimensional wires 28 can be extended in the same plane and arranged side by side. Final, step S110 can be executed to dispose the plural row wires 32 and the plural column wires 34 respectively on different sides of the row and column electrode array 16, such as the embodiments shown in FIG. 6 and FIG. 7, thereby completing production of the ultrasonic transducing device 10.

In step S104 and step S106, a production method of the two-dimensional electrode array 14 and the row and column electrode array 16 can plate a metal electrode on a substrate as a thin film. The metal electrode can be made of gold, copper, aluminum, silver or indium tin oxide (ITO), and practical application of the metal electrode is not limited to the foresaid material. Then, a yellow light process can be used to make a photoresist on the metal electrode, and a mask or a laser can be used to manufacture an electrode unit pattern of the two-dimensional electrode array 14 and/or the row and column electrode array 16 on the photoresist, and then other process such as exposure imaging, thin film etching, and photoresist removal can be applied to generate the two-dimensional electrode array 14 and the row and column electrode array 16.

In conclusion, the ultrasonic transducing device of the present invention can combine advantages of the two-dimensional electrode array and the row and column electrode array while eliminating disadvantages. In the preferred embodiment, each two-dimensional electrode unit of the two-dimensional electrode array can be used to independently emit the ultrasonic signal for the large scale scanning operation, and the row electrode assembly or the column electrode assembly of the row and column electrode array can be further used to alternately receive the ultrasonic signal, so as to conform to a requirement of the large scale scanning operation by small increase of the channel number, thereby applying for the current ultrasonic system. Besides, the ultrasonic transducing device of the present invention can accurately control the intervals between the two-dimensional electrode array and each electrode unit of the row and column electrode array, which can effectively eliminate artifacts and provide preferred performance of resolution. The ultrasonic signal emitted by the two-dimensional electrode array can be used for energy healing, and therefore the ultrasonic transducing device of the present invention can further accomplish combination design of diagnosis and treatment.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An ultrasonic transducing device, comprising:
a piezoelectric material layer having a first surface and a second surface opposite to each other, and comprising a plurality of grid-shaped units via division;
a two-dimensional electrode array disposed on the first surface and comprising plural two-dimensional electrode units set in an electrically independent manner; and
a row and column electrode array disposed on the second surface and comprising a row electrode assembly and a column electrode assembly, plural electrode rows of the row electrode assembly being set in the electrically independent manner, and plural row electrode units of each electrode row being electrically connected to each other, plural electrode columns of the column electrode assembly being set in the electrically independent, and plural column electrode units of each electrode column being electrically connected to each other.

2. The ultrasonic transducing device of claim 1, wherein a number of the two-dimensional electrode units is the same as a number of the plural electrode rows and a number of the plural electrode columns.

3. The ultrasonic transducing device of claim 1, wherein a size of each of the plurality of grid-shaped units is smaller than or equal to a size of a row electrode unit or a column electrode unit of the row and column electrode array.

4. The ultrasonic transducing device of claim 1, wherein the plural two-dimensional electrode unit and the row electrode assembly respectively belongs to a rectangular array, a ratio of an arrangement number of the two-dimensional electrode units on a side of the rectangular array to a row number of the row electrode assembly or a column number of the column electrode assembly is the same as a size ratio of each row and column electrode unit of the row electrode assembly to each two-dimensional electrode unit.

5. The ultrasonic transducing device of claim 1, wherein the two-dimensional electrode array further comprises plural two-dimensional wires respectively connected to the plural two-dimensional electrode units, an extending direction of each two-dimensional wire is perpendicular to a planar normal vector of the corresponding two-dimensional electrode unit.

6. The ultrasonic transducing device of claim 5, wherein an isolation layer is disposed between the two-dimensional wires of adjacent two-dimensional electrode units of the plural two-dimensional electrode units to form a height difference for bridging connection.

7. The ultrasonic transducing device of claim 5, wherein a sum of wire widths of the two-dimensional wires relevant to adjacent two-dimensional electrode units of the plural two-dimensional electrode unit is smaller than a size of each of the plural two-dimensional electrode units.

8. The ultrasonic transducing device of claim 1, wherein the row and column electrode array further comprises plural row wires and plural column wires respectively disposed on different sides of the row and column electrode array.

9. The ultrasonic transducing device of claim 8, wherein the plural row wires are disposed on the same side of the row and column electrode array, or alternately disposed on two opposite sides of the row and column electrode array.

10. The ultrasonic transducing device of claim 8, wherein the plural column wires are disposed on the same side of the row and column electrode array that is different from the side where on the plural row wires is disposed, or alternately disposed on two opposite sides of the row and column electrode array that are different from the opposite sides where on the plural row wires is disposed.

11. The ultrasonic transducing device of claim 1, wherein the ultrasonic transducing device utilizes the two-dimensional electrode array to emit an ultrasonic signal, and utilizes at least one of the row electrode assembly and the column electrode assembly to alternately receive the ultrasonic signal.

12. The ultrasonic transducing device of claim 1, wherein the two-dimensional electrode array is at least divided into a first region and a second region, the ultrasonic transducing device utilizes the first region to emit an ultrasonic signal and further utilizes the second region to receive the ultrasonic signal.

13. The ultrasonic transducing device of claim 1, wherein the ultrasonic transducing device utilizes at least one of the row electrode assembly and the column electrode assembly to emit an ultrasonic signal, and utilizes the two-dimensional electrode array and/or another electrode assembly of the row electrode assembly and the column electrode assembly to receive the ultrasonic signal.

14. The ultrasonic transducing device of claim 1, wherein the first surface is a back surface of the ultrasonic transducing device away from a target object, and the second surface is a matched surface of the ultrasonic transducing device facing the target object.

15. The ultrasonic transducing device of claim 1, wherein the first surface is one of an electrical positive surface and an electrical negative surface of the piezoelectric material layer, the second surface is another electrical surface of the electrical positive surface and the electrical negative surface of the piezoelectric material layer.

16. The ultrasonic transducing device of claim 1, wherein the ultrasonic transducing device further comprises anisotropic conductive adhesive disposed between the piezoelectric material layer and the two-dimensional electrode array, and disposed between the piezoelectric material layer and the row and column electrode array for providing directional conductive property.

17. A manufacturing method applied to an ultrasonic transducing device, comprising:
dividing the piezoelectric material layer into a plurality of grid-shaped units;
coating anisotropic conductive adhesive on a first surface and a second surface of the piezoelectric material layer that are opposite to each other;
fixing a two-dimensional electrode array on the first surface via the anisotropic conductive adhesive; and
fixing a row and column electrode array on the second surface via the anisotropic conductive adhesive.

18. The manufacturing method of claim 17, wherein a grid arrangement direction of the plurality of grid-shaped units on the first surface is different from a grid arrangement direction of the plurality of grid-shaped units on the second surface.

19. The manufacturing method of claim 17, further comprising:
disposing an isolation layer between two-dimensional wires relevant to adjacent two-dimensional electrode units of the two-dimensional electrode array to form a height difference for bridging connection.

20. The manufacturing method of claim 17, further comprising:
extending two-dimensional wires relevant to adjacent two-dimensional electrode units of the two-dimensional electrode array in the same plane and arranging the two-dimensional wires side by side;
wherein a sum of wire widths of the two-dimensional wires is smaller than a size of each of the adjacent two-dimensional electrode units.
